(19) United States
(12) Patent Application Publication
(10) Pub. No.: US 2012/0238108 A1
(43) Pub. Date: Sep. 20, 2012

(54) TWO-STAGE OZONE CURE FOR DIELECTRIC FILMS

(75) Inventors: Xiaolin Chen, San Ramon, CA (US); Jingmei Liang, San Jose, CA (US); Nitin K. Ingle, San Jose, CA (US); Shankar Venkataraman, San Jose, CA (US)

(73) Assignee: Applied Materials, Inc., Santa Clara, CA (US)

(21) Appl. No.: 13/227,161

(22) Filed: Sep. 7, 2011

Related U.S. Application Data
(60) Provisional application No. 61/452,362, filed on Mar. 14, 2011.

(51) Int. Cl. H01L 21/316

(52) U.S. Cl. 438/765; 257/E21.282

(57) ABSTRACT

A method of forming a silicon oxide layer is described. The method increases the oxygen content of a dielectric layer by curing the layer in a two-step ozone cure. The first step involves exposing the dielectric layer to ozone while the second step involves exposing the dielectric layer to ozone excited by a local plasma. This sequence can reduce or eliminate the need for a subsequent anneal following the cure step. The two-step ozone cures may be applied to silicon-and-nitrogen-containing film to convert the films to silicon oxide.

### CROSS-REFERENCES TO RELATED APPLICATIONS

This application claims the benefit of U.S. Provisional Application No. 61/452,362 by Chen et al, filed Mar. 14, 2011 and titled “TWO-STAGE OZONE CURE FOR DIELECTRIC FILMS” which is incorporated herein in its entirety for all purposes.

### BACKGROUND OF THE INVENTION

Semiconductor device geometries have dramatically decreased in size since their introduction several decades ago. Modern semiconductor fabrication equipment routinely produces devices with 45 nm, 32 nm, and 28 nm feature sizes, and new equipment is being developed and implemented to make devices with even smaller geometries. The decreasing feature sizes result in structural features on the device having decreased spatial dimensions. The widths of gaps and trenches on the device narrow to a point where the aspect ratio of gap depth to its width becomes high enough to make it challenging to fill the gap with dielectric material. The depositing dielectric material is prone to clog at the top before the gap completely fills, producing a void or seam in the middle of the gap.

Over the years, many techniques have been developed to avoid having dielectric material clog the top of a gap, or to “heal” the void or seam that has been formed. One approach has been to start with highly flowable precursor materials that may be applied in a liquid phase to a spinning substrate surface (e.g., SOG deposition techniques). These flowable precursors can flow into and fill very small substrate gaps without forming voids or weak seams. However, once these highly flowable materials are deposited, they have to be hardened into a solid dielectric material.

In many instances, the hardening process includes a heat treatment to remove carbon and hydroxyl groups from the deposited material to leave behind a solid dielectric such as silicon oxide. Unfortunately, the departing carbon and hydroxyl species often leave behind pores in the hardened dielectric that reduce the quality of the final material. In addition, the hardening dielectric also tends to shrink in volume, which can leave cracks and spaces at the interface of the dielectric and the surrounding substrate. In some instances, the volume of the hardened dielectric can decrease by 40% or more.

Thus, there is a need for new deposition processes and materials to form dielectric materials on structured substrates without generating voids, seams, or both, in substrate gaps and trenches. There is also a need for materials and methods of hardening flowable dielectric materials with fewer pores and a lower decrease in volume. This and other needs are addressed in the present application.

### BRIEF SUMMARY OF THE INVENTION

A method of forming a silicon oxide layer is described. The method increases the oxygen content of a dielectric layer by curing the layer in a two-step ozone cure. The first step involves exposing the dielectric layer to ozone while the second step involves exposing the dielectric layer to ozone excited by a local plasma. This sequence can reduce or eliminate the need for a subsequent anneal following the cure step. The two-step ozone cures may be applied to silicon-and-nitrogen-containing film to convert the films to silicon oxide.

Embodiments of the invention include methods of forming a silicon oxide layer on a substrate in a substrate processing region in a substrate processing chamber. The methods include transferring the substrate into the substrate processing region. The methods further include dual-stage curing a silicon-containing layer. The dual-stage curing operation includes flowing ozone into the substrate processing region. The dual-stage curing operation further includes exposing the silicon-containing layer to the ozone in a first curing stage while applying essentially no plasma power to the substrate processing region. The operation of exposing the silicon-containing layer converts the silicon-containing layer to a silicon-and-oxygen-containing layer. The dual-stage curing operation further includes exposing the silicon-and-oxygen-containing layer in a second curing stage while applying a plasma power to excite the ozone within the substrate processing region. The plasma power applied during the second curing stage is greater than the plasma power applied during the first curing stage. The silicon-and-oxygen-containing layer is converted to the silicon oxide layer during the second curing stage. The methods further include removing the substrate from the substrate processing region.

Additional embodiments and features are set forth in part in the description that follows, and in part will become apparent to those skilled in the art upon examination of the specification or may be learned by the practice of the invention. The features and advantages of the invention may be realized and attained by means of the instrumentalities, combinations, and methods described in the specification.

### BRIEF DESCRIPTION OF THE DRAWINGS

A further understanding of the nature and advantages of the present invention may be realized by reference to the remaining portions of the specification and the drawings wherein like reference numerals are used throughout the several drawings to refer to similar components. In some instances, a sublabel is associated with a reference numeral and follows a hyphen to denote one of multiple similar components. When reference is made to a reference numeral without specification to an existing sublabel, it is intended to refer to all such multiple similar components.

FIG. 1 is a flowchart illustrating selected steps for making a silicon oxide film according to embodiments of the invention.

FIG. 2 is another flowchart illustrating selected steps for forming a silicon oxide film in a substrate gap according to embodiments of the invention.

FIG. 3 is another flowchart illustrating selected steps for curing a spin-on dielectric film according to embodiments of the invention.

FIG. 4 shows a substrate processing system according to embodiments of the invention.

FIG. 5A shows a substrate processing chamber according to embodiments of the invention.

FIG. 5B shows a gas distribution showerhead according to embodiments of the invention.

### DETAILED DESCRIPTION OF THE INVENTION

A method of forming a silicon oxide layer is described. The method increases the oxygen content of a dielectric layer by curing the layer in a two-step ozone cure. The first step involves exposing the dielectric layer to ozone while the second step involves exposing the dielectric layer to ozone excited by a local plasma. This sequence can reduce or eliminate the need for a subsequent anneal following the cure step. The two-step ozone cures may be applied to silicon-and-nitrogen-containing film to convert the films to silicon oxide.

Without binding the coverage of the claims to hypothetical mechanisms which may or may not be entirely correct, a discussion of some details may prove beneficial. Exposing an as-deposited silicon-and-nitrogen-containing film to ozone first and then exposing it to plasma-excited ozone improves the conversion of the film to silicon oxide over performing either step alone. This may result from the relatively open network produced by depositions of silicon-and-nitrogen-containing films by, for example mixing a radical-nitrogen precursor with a carbon-free silicon-containing precursor. In general, these open networks are correlated with the formation of flowable films useful for filling gaps and trenches. The open network may allow ozone unexcited by a local plasma to penetrate more deeply within the film. This can extend the oxide conversion in the direction of the substrate. The second stage of further curing the film in a local-plasma-excited ozone has been found to further convert the film to silicon oxide. The sequence of ozone and local-plasma-excited ozone has been found to create silicon oxide without the assistance of a relatively high-temperature oxygen-treatment.

The reactivity of ozone lies between that of molecular oxygen and atomic oxygen. Molecular oxygen requires a higher temperature to activate the oxidation which results in a closure of the open silicon-and-nitrogen-containing network near the surface. This closure undesirably limits the oxidation in deeper portions of the silicon-nitrogen-and-hydrogen-containing layer. Atomic oxygen would react too readily at low temperatures and close the network as well. Ozone is found to offer the stability to penetrate deep into the open network while not requiring a high temperature to promote the oxidation. Subsequent excitation of ozone by a local-plasma has been found to simulate a high-temperature oxygen exposure. The resulting film of silicon oxide has been found to exhibit properties which may not evolve when the substrate is exposed to atmosphere outside the substrate processing region. Additional details about the methods and systems of forming the silicon oxide layer will now be described.

### Exemplary Silicon Oxide Formation Process

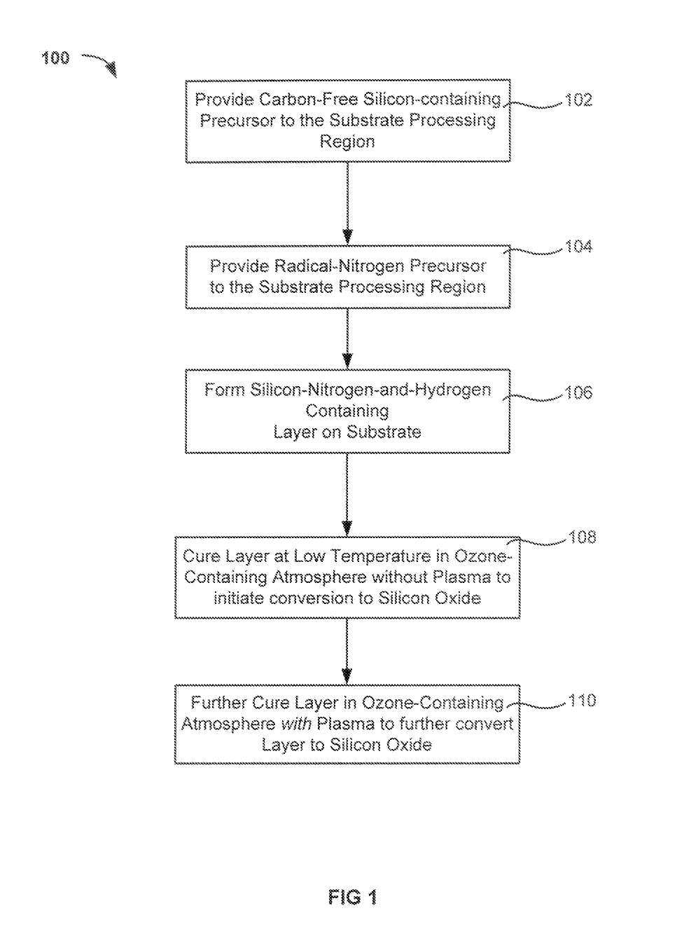

FIG. 1 is a flowchart showing selected steps in methods 100 of making silicon oxide films according to embodiments of the invention. The method 100 includes providing a silicon-containing precursor to a substrate processing region 102. The silicon-containing precursor may be a carbon-free silicon-containing precursor. The silicon-containing precursor may be, for example, a carbon-free silicon-and-nitrogen-containing precursor, a carbon-free silicon-and-hydrogen-containing precursor, or a carbon-free silicon-nitrogen-and-hydrogen-containing precursor, among other classes of carbon-free silicon-containing precursors. As will be discussed in detail shortly, an absence of carbon reduces the shrinkage of the deposited film. The silicon-containing precursor may be oxygen-free in addition to carbon-free. The lack of oxygen results in a lower concentration of silanol (Si—OH) groups in the silicon-and-nitrogen-containing layer formed from the precursors. Excess silanol moieties in the deposited film can cause increased porosity and shrinkage during post deposition steps that remove the hydroxyl (—OH) moieties from the deposited layer.

Specific examples of carbon-free silicon-containing precursors may include silyl-amines such as H₂N(SiH₃), HN(SiH₃)₂, and N(SiH₃)₃, among other silyl-amines. The flow rates of a silyl-amine may be greater than or about 200 sccm, greater than or about 300 sccm or greater than or about 500 sccm in different embodiments. All flow rates given herein refer to a dual chamber substrate processing system. Single wafer systems would require half these flow rates and other wafer sizes would require flow rates scaled by the processed area. These silyl-amines may be mixed with additional gases that may act as carrier gases, reactive gases, or both. Exemplary additional gases include H₂, N₂, NH₃, He, and Ar, among other gases. Examples of carbon-free silicon-containing precursors may also include silane (SiH₄) either alone or mixed with other silicon (e.g., N(SiH₃)₃), hydrogen (e.g., H₂), and/or nitrogen (e.g., N₂, NH₃) containing gases. Carbon-free silicon-containing precursors may also include disilane, trisilane, even higher-order silanes, and chlorinated silanes, alone or in combination with one another or the previously mentioned carbon-free silicon-containing precursors.

A radical precursor may also be provided to the substrate processing region 104. The radical precursor may be a nitrogen-containing radical precursor which will be referred to herein as a radical-nitrogen precursor. The radical-nitrogen precursor is a nitrogen-radical-containing precursor that was generated outside the substrate processing region from a more stable nitrogen precursor. A stable precursor may be referred to herein as an unexcited precursor to indicate that the precursor has not yet passed through a plasma. A stable nitrogen precursor compound containing NH₃, hydrazine (N₂H₄) and/or N₂ may be activated in a chamber plasma region or a remote plasma system (RPS) outside the processing chamber to form the radical-nitrogen precursor, which is then transported into the substrate processing region. The term “remote plasma region” will be used to refer to all possibilities (such as RPS or chamber plasma region) for remotely exciting the stable precursor. The stable nitrogen precursor may also be a mixture comprising NH₃ & N₂, NH₃ & H₂, NH₃ & N₂ & H₂ and N₂ & H₂, in different embodiments. Hydrazine (N₂H₂) may also be used in place of or in combination with NH₃ and in the mixtures involving N₂ and H₂. The flow rate of the stable nitrogen precursor may be greater than or about 300 sccm, greater than or about 500 sccm or greater than or about 700 sccm in different embodiments. The radical-nitrogen precursor produced in the chamber plasma region may be one or more of .N, .NH, .NH₂, etc., and may also be accompanied by ionized species formed in the plasma. Sources of oxygen may also be combined with the more stable nitrogen precursor in the remote plasma which will act to pre-load the film with oxygen while decreasing flowability. Sources of oxygen may include one or more of O₂, H₂O, O₃, H₂O₂, N₂O, NO or NO₂.

In embodiments employing a chamber plasma region, the radical-nitrogen precursor is generated in a section of the substrate processing region partitioned from a deposition region where the precursors mix and react to deposit the silicon-and-nitrogen-containing layer on a deposition substrate (e.g., a semiconductor wafer). The radical-nitrogen precursor may also be accompanied by a carrier gas such as hydrogen (H₂), nitrogen (N₂), helium, etc. The substrate processing region may be described herein as “plasma-free” during the growth of the silicon-nitrogen-and-hydrogen-containing layer and during the low temperature ozone cure. “Plasma-free” does not necessarily mean the region is devoid of plasma. The borders of the plasma in the chamber plasma region are hard to define and may encroach upon the substrate processing region through the apertures in the showerhead. In the case of an inductively-coupled plasma, e.g., a small amount of ionization may be initiated within the plasma-free substrate processing region directly. Furthermore, a low intensity plasma may be created in the plasma-free substrate processing region without eliminating the flowable nature of the forming film. All causes for a plasma having much lower ion density than the chamber plasma region during the creation of the radical nitrogen precursor do not deviate from the scope of “plasma-free” as used herein.

In the plasma-free substrate processing region, the carbon-free silicon-containing precursor and the radical-nitrogen precursor mix and react to deposit a silicon-nitrogen-and-hydrogen-containing film on the deposition substrate 106. The deposited silicon-nitrogen-and-hydrogen-containing film may deposit conformally with some recipe combinations in embodiments. In other embodiments, the deposited silicon-nitrogen-and-hydrogen-containing film has flowable characteristics unlike conventional silicon nitride (Si₃N₄) film deposition techniques. The flowable nature of the formation allows the film to flow into narrow gaps trenches and other structures on the deposition surface of the substrate. Generally speaking, the films may be silicon-containing films in the event alternative precursors are used. For example, the silicon-containing films may be silicon-and-carbon-containing films when a carbon-containing precursor is used in place of the nitrogen-containing precursor. Films made using carbon-containing precursors may shrink more than the corresponding nitrogen-containing films, but would still benefit from the two-stage ozone cure described herein.

When nitrogen films are used, the nitrogen may originate from either (or both) of the radical precursor or the unexcited precursor. The carbon-free silicon-containing precursor may be essentially nitrogen-free, in embodiments. However, in other embodiments, both the carbon-free silicon-containing precursor and the radical-nitrogen precursor contain nitrogen. Lastly, the radical precursor may be essentially nitrogen-free, in embodiments, and the nitrogen for the silicon-nitrogen-and-hydrogen-containing layer may be supplied by the carbon-free silicon-containing precursor. So most generally speaking, the radical precursor may be referred to herein as a “radical-nitrogen- and/or -hydrogen precursor,” which means that the precursor contains nitrogen and/or hydrogen. Analogously, the precursor flowed into the plasma region to form the radical-nitrogen- and/or -hydrogen precursor may be referred to as a nitrogen- and/or -hydrogen-containing precursor. These generalizations may be applied to each of the embodiments disclosed herein. In embodiments, the nitrogen- and/or -hydrogen-containing precursor comprises hydrogen (H₂) while the radical-nitrogen- and/or -hydrogen precursor comprises .H, etc.

Returning to the specific example shown in FIG. 1, the flowability of a silicon-nitrogen-and-hydrogen-containing film may be due to a variety of properties which result from mixing a radical-nitrogen precursors with a carbon-free silicon-containing precursor. These properties may include a significant hydrogen component in the deposited film and/or the presence of short chained polysilazane polymers. These short chains grow and network to form more dense dielectric material during and after the formation of the film. For example the deposited film may have a silazane-type, Si—NH—Si backbone (i.e., a carbon-free Si—N—H film). When both the silicon-containing precursor and the radical precursor are carbon-free, the deposited silicon-nitrogen-and-hydrogen-containing film is also substantially carbon-free. Of course, “carbon-free” does not necessarily mean the film lacks even trace amounts of carbon. Carbon contaminants may be present in the precursor materials that find their way into the deposited silicon-and-nitrogen-containing layer. The amount of these carbon impurities however are much less than would be found in a silicon-containing precursor having a carbon moiety (e.g., TEOS, TMDSO, etc.).

Following the deposition of the silicon-nitrogen-and-hydrogen-containing layer, the deposition substrate may be cured in two sequential stages. The first curing stage involves exposing the silicon-nitrogen-and-hydrogen-containing layer to an ozone-containing atmosphere 108. Ozone is generated outside the plasma-free substrate processing region, in embodiments, and flowed into the plasma-free substrate processing region. Essentially no plasma power is applied to the plasma-free substrate processing region during the first ozone curing stage. Essentially no plasma power is used to describe the application of no plasma power, but also small amounts of power which do not functionally change the activity of the exposure. Absence of plasma, in embodiments, avoids generation of atomic oxygen which would close the near surface network and thwart subsurface oxidation. This first curing stage reduces the concentration of nitrogen while increasing the concentration of oxygen in the film. The reduction of nitrogen and increase in oxygen occurs not only near the surface, but also in the subsurface region due to the ability of relatively stable ozone to penetrate the open network of the silicon-nitrogen-and-hydrogen layer.

Following the first curing stage, the silicon-nitrogen-and-hydrogen-containing layer has been transformed into a silicon-and-oxygen-containing layer. During the second curing stage (operation 110), the silicon-and-oxygen-containing layer is further exposed to an ozone-containing atmosphere. However, the ozone-containing atmosphere is excited by applying plasma power to the substrate processing region during the second stage. Local plasma excitation of the ozone generates more reactive species which have been found to convert the silicon-and-oxygen-containing layer to silicon oxide. The first curing stage may be stabilizing the open network such that these more reactive oxygen species can penetrate the film and complete the transition to a silicon oxide film, in embodiments of the invention. RF plasma frequencies may be one or a combination of RF frequencies (e.g. 350 kHz, 13.5 MHz and/or 2.4 GHz). Other frequencies are possible especially in regions where the other frequencies do not interfere with local frequencies allocated for communication. The plasma power applied during the second curing stage may be less than or about 1000 Watts, less than or about 1500 Watts, less than or about 2000 Watts, between about 100 Watts and about 2000 Watts, between about 200 Watts and about 1000 Watts or between about 300 Watts and about 600 Watts in different embodiments.

Next, assorted parameters are described which apply to either or both of the first and second curing stages. The deposition substrate may remain in the substrate processing region for curing, or the substrate may be transferred to a different chamber where the ozone-containing atmosphere is introduced. The curing temperature of the substrate during either/both stages may be less than or about 400° C., less than or about 300° C., less than or about 250° C., less than or about 225° C., less than or about 200° C. or less than or about 150° C. in different embodiments. The temperature of the substrate may be greater than or about room temperature (25° C.), greater than or about 50° C., greater than or about 70° C., greater than or about 100° C., greater than or about 125° C., greater than or about 150° C. or greater than or about 200° C. in different embodiments. Any of the upper bounds may be combined with any of the lower bounds to form additional ranges for the substrate temperature according to additional disclosed embodiments. The flow rate of the ozone (just the ozone contribution) into the substrate processing region during either/both of the cure stages may be greater than or about 500 sccm, greater than or about 1 slm, greater than or about 2 slm or greater than or about 2 slm, in disclosed embodiments. The partial pressure of ozone during either/both cure stages may be greater than or about 20 Torr, greater than or about 30 Torr, greater than or about 50 Torr or greater than or about 100 Torr, in disclosed embodiments. Under some conditions (e.g. between substrate temperatures from about 100° C. to about 200° C.) the conversion has been found to be substantially complete so a relatively high temperature anneal in an oxygen-containing environment may be unnecessary in embodiments. In some cases, exposure to an increasing temperature from below or about 250° C. to a temperature above 400° C. (e.g. 550° C.) has furthered the conversion from the silicon-nitrogen-and-hydrogen-containing film to the silicon oxide film.

Following curing of the silicon-and-nitrogen-containing containing layer, the deposition substrate may not require annealing in an oxygen-containing atmosphere at temperatures higher than the curing temperature(s). Substrate temperatures during oxygen (O₂, NO₂, NO, H₂O, H₂O₂, etc.) anneals are necessarily higher to promote the reactivity and/or increase the density of the silicon oxide film. Removing these higher temperature anneals (which can be around 400° C. or higher) improves yield and performance of integrated circuit devices. The second curing stage achieves essentially the same conversion efficacy as a prior art oxygen anneal, in embodiments of the invention.

The ozone-containing atmospheres of each of the curing stages provide oxygen to convert the silicon-nitrogen-and-hydrogen-containing film into the silicon oxide (SiO₂) film. As noted previously, the lack of carbon in the silicon-nitrogen-and-hydrogen-containing film results in significantly fewer pores formed in the final silicon oxide film. It also results in less volume reduction (i.e., shrinkage) of the film during the conversion to the silicon oxide. For example, where a silicon-nitrogen-carbon layer formed from carbon-containing silicon-containing precursors may shrink by 40 vol. % or more when converted to silicon oxide, the substantially carbon-free silicon-and-nitrogen-containing films may shrink by about 15 vol. % or less.

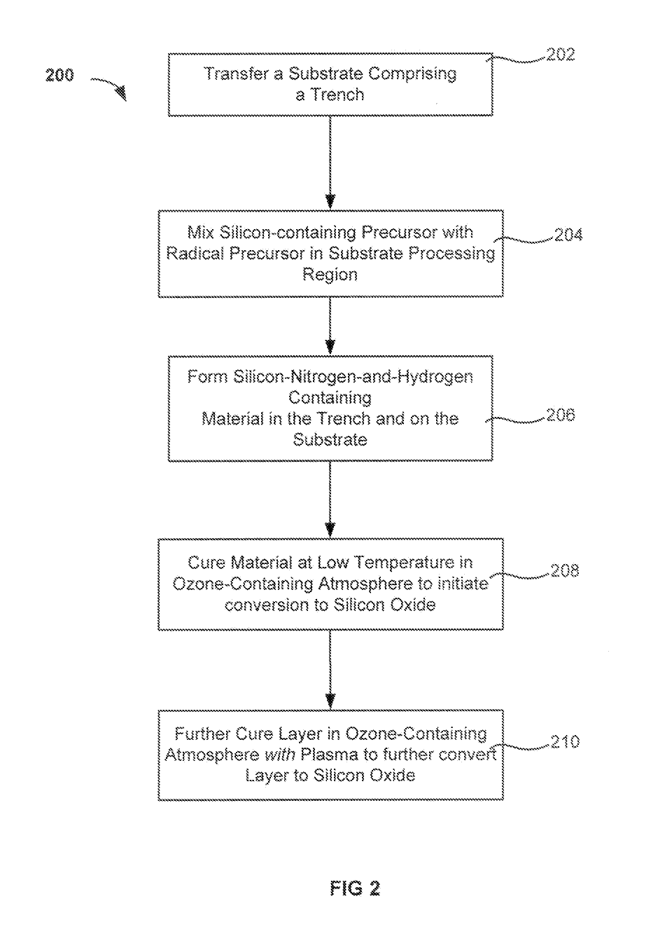

Referring now to FIG. 2, another flowchart is shown illustrating selected steps in a method 200 for forming a silicon oxide film in a substrate gap according to embodiments of the invention. The method 200 may include transferring a substrate comprising a gap into a substrate processing region (operation 202). The substrate may have a plurality of gaps for the spacing and structure of device components (e.g., transistors) formed on the substrate. The gaps may have a height and width that define an aspect ratio (AR) of the height to the width (i.e., H/W) that is significantly greater than 1:1 (e.g., 5:1 or more, 6:1 or more, 7:1 or more, 8:1 or more, 9:1 or more, 10:1 or more, 11:1 or more, 12:1 or more, etc.). In many instances the high AR is due to small gap widths of that range from about 90 nm to about 22 nm or less (e.g., less than 90 nm, 65 nm, 50 nm, 45 nm, 32 nm, 22 nm, 16 nm, etc.).

A silicon-containing precursor is mixed with a radical precursor in the substrate processing region (operation 204). A flowable silicon-nitrogen-and-hydrogen-containing layer is deposited on the substrate (operation 206). Because the layer is flowable, it can fill gaps with high aspect ratios without creating voids or weak seams around the center of the filling material. For example, a depositing flowable material is less likely to prematurely clog the top of a gap before it is completely filled to leave a void in the middle of the gap.

The as-deposited silicon-nitrogen-and-hydrogen-containing layer may then be cured in a first curing stage (operation 208) and a second curing stage (operation 210) to transition the silicon-nitrogen-and-hydrogen-containing layer to silicon oxide. Further anneals may not be necessary, in embodiments of the invention, due to the presence of the second curing stage.

Curing as-deposited silicon-nitrogen-and-hydrogen-containing layer in multiple sequential stages, as described herein, produces a silicon oxide layer on the substrate, including the substrate gap 208. In embodiments, the processing parameters of operations 208 and 210 possess the same ranges described with reference to operations 108 and 110 of FIG. 1. As noted above, the silicon oxide layer has fewer pores and less volume reduction than similar layers formed with carbon-containing precursors that have significant quantities of carbon present in the layer before the heat treatment step. In many cases, the volume reduction is slight enough (e.g., about 15 vol. % or less) to avoid post heat treatment steps to fill, heal, or otherwise eliminate spaces that form in the gap as a result of the shrinking silicon oxide. In some embodiments, the silicon oxide layer in the trench is substantially void-free.

Silicon oxide films prepared according to embodiments of the invention may exhibit a reduced wet etch rate ratio (WERR) compared to films prepared according to the prior art. The reduced WERR is thought to result from an increased density of the silicon oxide film. Dielectric films have been evaluated herein by measuring the wet etch rate (WER) and calculating a wet etch rate ratio (WERR). These measurements were made by performing a timed etch in a hydrofluoric acid based solution and calculating the etch rate in nanometers per second. A WERR is created by comparing the etch rate of a dielectric sample with that of a thermal silicon oxide in the same solution. A common buffered oxide etch solution includes a 6:1 volume ratio of 40% NH₄F in water to 49% HF in water. This solution will etch thermally grown silicon oxide at approximately 2 nanometres per second at 25° C. Other methods of forming silicon oxide will typically result in silicon oxide films having faster wet etch rates. Faster wet etch rates generally imply that the candidate silicon oxide film has a lower density than thermally grown silicon oxide. Silicon oxide films formed according to the methods presented herein may have a WERR of less than or about 3.5, less than or about 3.0 or less than or about 2.5, in embodiments of the invention.

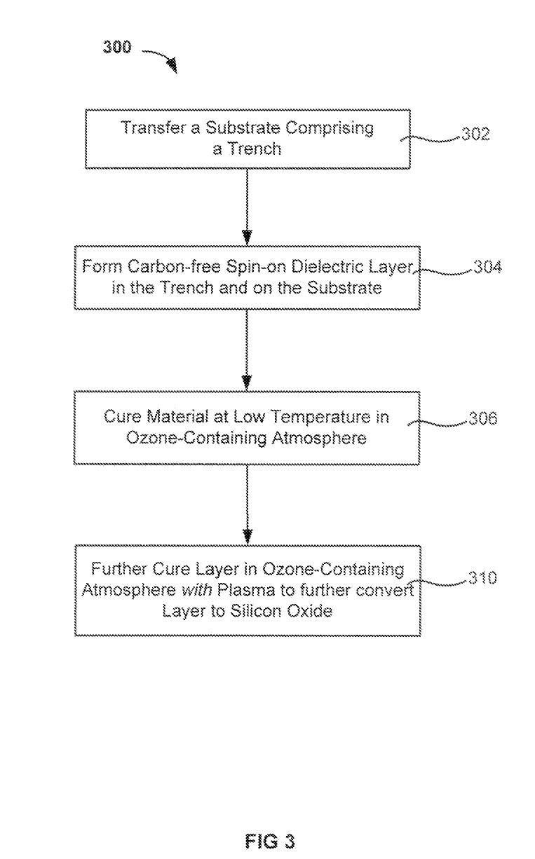

FIG. 3 is another flowchart illustrating selected steps in an exemplary method of making a silicon oxide film according to embodiments of the invention. The methods 300 may include transferring a patterned substrate having a trench into a spin-on dielectric (SOD) apparatus. A carbon-free silicon-nitrogen-and-hydrogen-containing material is poured onto the patterned substrate and the substrate may be rotated to disperse the dielectric layer evenly (operation 304). As-deposited, the spin-on dielectric (SOD) layer resides in the trench and may reside over the other regions of the substrate. The SOD layer comprises silicon and nitrogen and is cured in multiple stages (306 and 310) under similar conditions to the corresponding operations of FIGS. 1-2 to oxidize the SOD layer to form a silicon oxide layer. The substrate is maintained at the same relatively low temperatures in an ozone-containing environment in order to allow the oxidation to occur closer to the substrate (closer to the bottom of the layer) and within the trench. Subsequent high temperature oxygen anneals and higher temperature inert anneals may or may not be employed, in embodiments of the invention, to further oxidize and densify the SOD layer.

### Exemplary Silicon Oxide Deposition System

Deposition chambers that may implement embodiments of the present invention may include high-density plasma chemical vapor deposition (HDP-CVD) chambers, plasma enhanced chemical vapor deposition (PECVD) chambers, sub-atmospheric chemical vapor deposition (SACVD) chambers, and thermal chemical vapor deposition chambers, among other types of chambers. Specific examples of CVD systems that may implement embodiments of the invention include the CENTURA ULTIMA® HDP-CVD chambers/systems, and PRODUCER® PECVD chambers/systems, available from Applied Materials, Inc. of Santa Clara, Calif.

Examples of substrate processing chambers that can be used with exemplary methods of the invention may include those shown and described in co-assigned U.S. Provisional Patent App. No. 60/803,499 to Lubomirsky et al, filed May 30, 2006, and titled “PROCESS CHAMBER FOR DIELECTRIC GAPFILL,” the entire contents of which is herein incorporated by reference for all purposes. Additional exemplary systems may include those shown and described in U.S. Pat. Nos. 6,387,207 and 6,830,624, which are also incorporated herein by reference for all purposes.

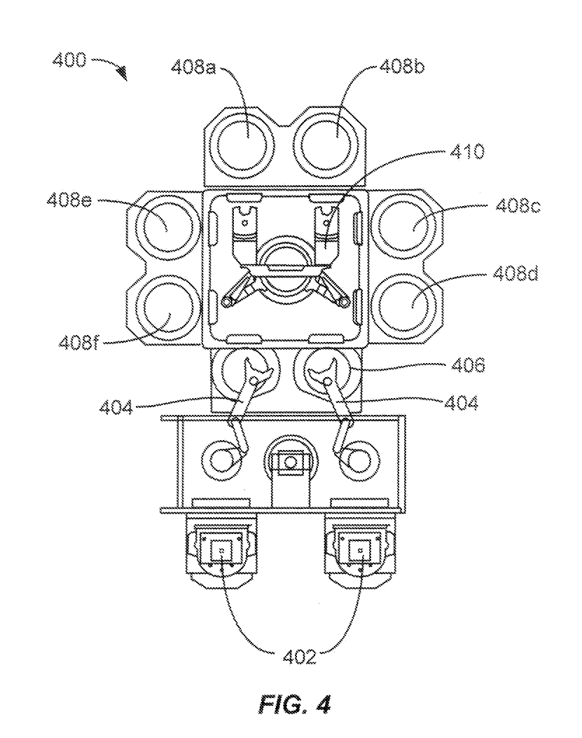

Embodiments of the deposition systems may be incorporated into larger fabrication systems for producing integrated circuit chips. FIG. 4 shows one such system 400 of deposition, baking and curing chambers according to disclosed embodiments. In the figure, a pair of FOUPs (front opening unified pods) 402 supply substrate substrates (e.g., 300 mm diameter wafers) that are received by robotic arms 404 and placed into a low pressure holding area 406 before being placed into one of the substrate processing chambers 408a-f. A second robotic arm 410 may be used to transport the substrate wafers from the holding area 406 to the substrate processing chambers 408a-f and back.

The substrate processing chambers 408a-f may include one or more system components for depositing, annealing, curing and/or etching a flowable dielectric film on the substrate wafer. In one configuration, two pairs of the processing chamber (e.g., 408c-d and 408e-f) may be used to deposit the flowable dielectric material on the substrate, and the third pair of processing chambers (e.g., 408a-b) may be used to anneal the deposited dielectric. In another configuration, the same two pairs of processing chambers (e.g., 408c-d and 408e-f) may be configured to both deposit and anneal a flowable dielectric film on the substrate, while the third pair of chambers (e.g., 408a-b) may be used for UV or E-beam curing of the deposited film. In still another configuration, all three pairs of chambers (e.g., 408a-f) may be configured to deposit and cure a flowable dielectric film on the substrate. In yet another configuration, two pairs of processing chambers (e.g., 408c-d and 408e-f) may be used for both deposition and UV or E-beam curing of the flowable dielectric, while a third pair of processing chambers (e.g. 408a-b) may be used for annealing the dielectric film. Any one or more of the processes described may be carried out on chamber(s) separated from the fabrication system shown in different embodiments.

In addition, one or more of the substrate processing chambers 408a-f may be configured as a wet treatment chamber. These process chambers include heating the flowable dielectric film in an atmosphere that includes moisture. Thus, embodiments of system 400 may include wet treatment chambers as substrate processing chambers 408a-b and anneal processing chambers for substrate processing chambers 408c-d to perform both wet and dry anneals on the deposited dielectric film.

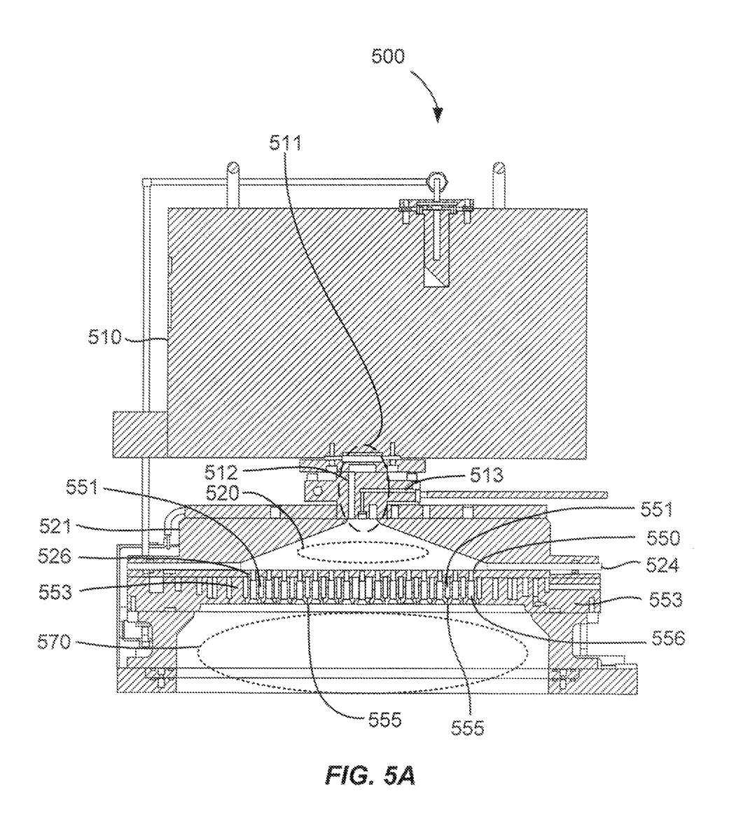

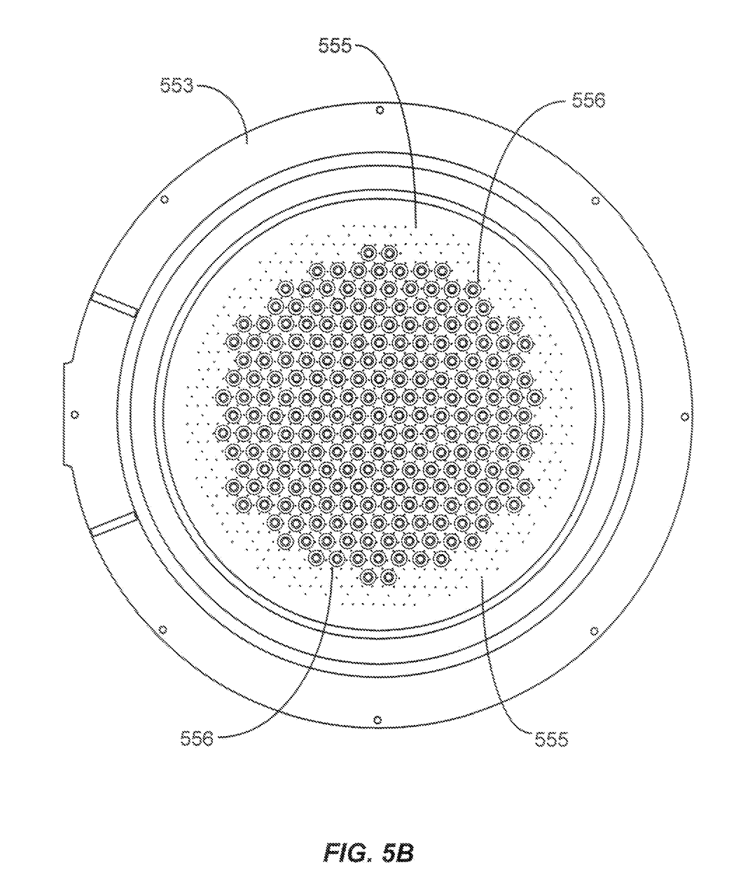

FIG. 5A is a substrate processing chamber 500 according to disclosed embodiments. A remote plasma system (RPS) 510 may process a gas which then travels through a gas inlet assembly 511. Two distinct gas supply channels are visible within the gas inlet assembly 511. A first channel 512 carries a gas that passes through the remote plasma system (RPS 510), while a second channel 513 bypasses the RPS 510. The first channel 512 may be used for the process gas and the second channel 513 may be used for a treatment gas in disclosed embodiments. The lid (or conductive top portion) 521 and a perforated partition (showerhead 553) are shown with an insulating ring 524 in between, which allows an AC potential to be applied to the lid 521 relative to showerhead 553. The process gas travels through first channel 512 into chamber plasma region 520 and may be excited by a plasma in chamber plasma region 520 alone or in combination with RPS 510. The combination of chamber plasma region 520 and/or RPS 510 may be referred to as a remote plasma system herein. The perforated partition (also referred to as a showerhead) 553 separates chamber plasma region 520 from a substrate processing region 570 beneath showerhead 553. Showerhead 553 allows a plasma present in chamber plasma region 520 to avoid directly exciting gases in substrate processing region 570, while still allowing excited species to travel from chamber plasma region 520 into substrate processing region 570.

Showerhead 553 is positioned between chamber plasma region 520 and substrate processing region 570 and allows plasma effluents (excited derivatives of precursors or other gases) created within chamber plasma region 520 to pass through a plurality of through-holes 556 that traverse the thickness of the plate. The showerhead 553 also has one or more hollow volumes 551 which can be filled with a precursor in the form of a vapor or gas (such as a silicon-containing precursor) and pass through small holes 555 into substrate processing region 570 but not directly into chamber plasma region 520. Showerhead 553 is thicker than the length of the smallest diameter 550 of the through-holes 556 in this disclosed embodiment. In order to maintain a significant concentration of excited species penetrating from chamber plasma region 520 to substrate processing region 570, the length 526 of the smallest diameter 550 of the through-holes may be restricted by forming larger diameter portions of through-holes 556 part way through the showerhead 553. The length of the smallest diameter 550 of the through-holes 556 may be the same order of magnitude as the smallest diameter of the through-holes 556 or less in disclosed embodiments.

In the embodiment shown, showerhead 553 may distribute (via through-holes 556) process gases which contain oxygen, hydrogen and/or nitrogen and/or plasma effluents of such process gases upon excitation by a plasma in chamber plasma region 520. In embodiments, the process gas introduced into the RPS 510 and/or chamber plasma region 520 through first channel 512 may contain one or more of oxygen (O₂), ozone (O₃), N₂O, NO, NO₂, NH₃, NₓH_{y} including N₂H₄, silane, disilane, TSA and DSA. The process gas may also include a carrier gas such as helium, argon, nitrogen (N₂), etc. The second channel 513 may also deliver a process gas and/or a carrier gas, and/or a film-curing gas (e.g. O₃) used to remove an unwanted component from the growing or as-deposited film. Plasma effluents may include ionized or neutral derivatives of the process gas and may also be referred to herein as a radical-oxygen precursor and/or a radical-nitrogen precursor referring to the atomic constituents of the process gas introduced.

In embodiments, the number of through-holes 556 may be between about 60 and about 2000. Through-holes 556 may have a variety of shapes but are most easily made round. The smallest diameter 550 of through-holes 556 may be between about 0.5 mm and about 20 mm or between about 1 mm and about 6 mm in disclosed embodiments. There is also latitude in choosing the cross-sectional shape of through-holes, which may be made conical, cylindrical or a combination of the two shapes. The number of small holes 555 used to introduce a gas into substrate processing region 570 may be between about 100 and about 5000 or between about 500 and about 2000 in different embodiments. The diameter of the small holes 555 may be between about 0.1 mm and about 2 mm.

FIG. 5B is a bottom view of a showerhead 553 for use with a processing chamber according to disclosed embodiments. Showerhead 553 corresponds with the showerhead shown in FIG. 5A. Through-holes 556 are depicted with a larger inner-diameter (ID) on the bottom of showerhead 553 and a smaller ID at the top. Small holes 555 are distributed substantially evenly over the surface of the showerhead, even amongst the through-holes 556 which helps to provide more even mixing than other embodiments described herein.

An exemplary film is created on a substrate supported by a pedestal (not shown) within substrate processing region 570 when plasma effluents arriving through through-holes 556 in showerhead 553 combine with a silicon-containing precursor arriving through the small holes 555 originating from hollow volumes 551. Though substrate processing region 570 may be equipped to support a plasma for other processes such as curing, no plasma is present during the growth of the exemplary film.

A plasma may be ignited either in chamber plasma region 520 above showerhead 553 or substrate processing region 570 below showerhead 553. A plasma is present in chamber plasma region 520 to produce the radical nitrogen precursor from an inflow of a nitrogen-and-hydrogen-containing gas. An AC voltage typically in the radio frequency (RF) range is applied between the conductive top portion (lid 521) of the processing chamber and showerhead 553 to ignite a plasma in chamber plasma region 520 during deposition. An RF power supply generates a high RF frequency of 13.56 MHz but may also generate other frequencies alone or in combination with the 13.56 MHz frequency.

The top plasma may be left at low or no power when the bottom plasma in the substrate processing region 570 is turned on during the second curing stage or clean the interior surfaces bordering substrate processing region 570. A plasma in substrate processing region 570 is ignited by applying an AC voltage between showerhead 553 and the pedestal or bottom of the chamber. A cleaning gas may be introduced into substrate processing region 570 while the plasma is present.

The pedestal may have a heat exchange channel through which a heat exchange fluid flows to control the temperature of the substrate. This configuration allows the substrate temperature to be cooled or heated to maintain relatively low temperatures (from room temperature through about 120° C.). The heat exchange fluid may comprise ethylene glycol and water. The wafer support platter of the pedestal (preferably aluminum, ceramic, or a combination thereof) may also be resistively heated in order to achieve relatively high temperatures (from about 120° C. through about 1100° C.) using an embedded single-loop embedded heater element configured to make two full turns in the form of parallel concentric circles. An outer portion of the heater element may run adjacent to a perimeter of the support platter, while an inner portion runs on the path of a concentric circle having a smaller radius. The wiring to the heater element passes through the stem of the pedestal.

The substrate processing system is controlled by a system controller. In an exemplary embodiment, the system controller includes a hard disk drive, a floppy disk drive and a processor. The processor contains a single-board computer (SBC), analog and digital input/output boards, interface boards and stepper motor controller boards. Various parts of CVD system conform to the Versa Modular European (VME) standard which defines board, card cage, and connector dimensions and types. The VME standard also defines the bus structure as having a 16-bit data bus and a 24-bit address bus.

The system controller controls all of the activities of the CVD machine. The system controller executes system control software, which is a computer program stored in a computer-readable medium. Preferably, the medium is a hard disk drive, but the medium may also be other kinds of memory. The computer program includes sets of instructions that dictate the timing, mixture of gases, chamber pressure, chamber temperature, RF power levels, susceptor position, and other parameters of a particular process. Other computer programs stored on other memory devices including, for example, a floppy disk or other another appropriate drive, may also be used to instruct the system controller.

A process for depositing a film stack on a substrate or a process for cleaning a chamber can be implemented using a computer program product that is executed by the system controller. The computer program code can be written in any conventional computer readable programming language: for example, 68000 assembly language, C, C++, Pascal, Fortran or others. Suitable program code is entered into a single file, or multiple files, using a conventional text editor, and stored or embodied in a computer usable medium, such as a memory system of the computer. If the entered code text is in a high level language, the code is compiled, and the resultant compiler code is then linked with an object code of precompiled Microsoft Windows® library routines. To execute the linked, compiled object code the system user invokes the object code, causing the computer system to load the code in memory. The CPU then reads and executes the code to perform the tasks identified in the program.

The interface between a user and the controller is via a flat-panel touch-sensitive monitor. In the preferred embodiment two monitors are used, one mounted in the clean room wall for the operators and the other behind the wall for the service technicians. The two monitors may simultaneously display the same information, in which case only one accepts input at a time. To select a particular screen or function, the operator touches a designated area of the touch-sensitive monitor. The touched area changes its highlighted color, or a new menu or screen is displayed, confirming communication between the operator and the touch-sensitive monitor. Other devices, such as a keyboard, mouse, or other pointing or communication device, may be used instead of or in addition to the touch-sensitive monitor to allow the user to communicate with the system controller.

As used herein “substrate” may be a support substrate with or without layers formed thereon. The support substrate may be an insulator or a semiconductor of a variety of doping concentrations and profiles and may, for example, be a semiconductor substrate of the type used in the manufacture of integrated circuits. A layer of “silicon oxide” may include minority concentrations of other elemental constituents such as nitrogen, hydrogen, carbon and the like. In some embodiments, silicon oxide consists essentially of silicon and oxygen. The term “precursor” is used to refer to any process gas which takes part in a reaction to either remove material from or deposit material onto a surface. A gas in an “excited state” describes a gas wherein at least some of the gas molecules are in vibrationally-excited, dissociated and/or ionized states. A gas (or precursor) may be a combination of two or more gases (or precursors). A “radical precursor” is used to describe plasma effluents (a gas in an excited state which is exiting a plasma) which participate in a reaction to either remove material from or deposit material on a surface. A “radical-nitrogen precursor” is a radical precursor which contains nitrogen and a “radical-hydrogen precursor” is a radical precursor which contains hydrogen. The phrase “inert gas” refers to any gas which does not form chemical bonds when etching or being incorporated into a film. Exemplary inert gases include noble gases but may include other gases so long as no chemical bonds are formed when (typically) trace amounts are trapped in a film.

The term “trench” is used throughout with no implication that the etched geometry has a large horizontal aspect ratio. Viewed from above the surface, trenches may appear circular, oval, polygonal, rectangular, or a variety of other shapes. The term “via” is used to refer to a low aspect ratio trench which may or may not be filled with metal to form a vertical electrical connection. As used herein, a conformal layer refers to a generally uniform layer of material on a surface in the same shape as the surface, i.e., the surface of the layer and the surface being covered are generally parallel. A person having ordinary skill in the art will recognize that the deposited material likely cannot be 100% conformal and thus the term “generally” allows for acceptable tolerances.

Having described several embodiments, it will be recognized by those of skill in the art that various modifications, alternative constructions, and equivalents may be used without departing from the spirit of the invention. Additionally, a number of well-known processes and elements have not been described in order to avoid unnecessarily obscuring the present invention. Accordingly, the above description should not be taken as limiting the scope of the invention.

Where a range of values is provided, it is understood that each intervening value, to the tenth of the unit of the lower limit unless the context clearly dictates otherwise, between the upper and lower limits of that range is also specifically disclosed. Each smaller range between any stated value or intervening value in a stated range and any other stated or intervening value in that stated range is encompassed. The upper and lower limits of these smaller ranges may independently be included or excluded in the range, and each range where either, neither or both limits are included in the smaller ranges is also encompassed within the invention, subject to any specifically excluded limit in the stated range. Where the stated range includes one or both of the limits, ranges excluding either or both of those included limits are also included.

As used herein and in the appended claims, the singular forms “a”, “an”, and “the” include plural referents unless the context clearly dictates otherwise. Thus, for example, reference to “a process” includes a plurality of such processes and reference to “the precursor” includes reference to one or more precursor and equivalents thereof known to those skilled in the art, and so forth.

Also, the words “comprise,” “comprising,” “include,” “including,” and “includes” when used in this specification and in the following claims are intended to specify the presence of stated features, integers, components, or steps, but they do not preclude the presence or addition of one or more other features, integers, components, steps, acts, or groups.

What is claimed is:

1. A method of forming a silicon oxide layer on a substrate in a substrate processing region in a substrate processing chamber, the method comprising:
transferring the substrate into the substrate processing region;
dual-stage curing a silicon-containing layer, wherein the dual-stage curing operation comprises:
flowing ozone into the substrate processing region,
exposing the silicon-containing layer to the ozone in a first curing stage while applying essentially no plasma power to the substrate processing region, wherein the operation of exposing the silicon-containing layer converts the silicon-containing layer to a silicon-and-oxygen-containing layer, and
exposing the silicon-and-oxygen-containing layer in a second curing stage while applying a plasma power to excite the ozone within the substrate processing region, wherein the plasma power applied during the second curing stage is greater than the plasma power applied during the first curing stage and wherein the silicon-and-oxygen-containing layer is converted to the silicon oxide layer; and
removing the substrate from the substrate processing region.

2. The method of claim 1 wherein a temperature of the substrate is less than or about 400° C. during each of the first curing stage and the second curing stage.

3. The method of claim 1 wherein a temperature of the substrate is greater than or about 70° C. and less than or about 250° C. during the first curing stage.

4. The method of claim 1 wherein a temperature of the substrate is greater than or about 70° C. and less than or about 250° C. during the second curing stage.

5. The method of claim 1 wherein the silicon oxide layer has a WERR of less than or about 3.5.

6. The method of claim 1 wherein the silicon oxide layer has a WERR of less than or about 3.0.

7. The method of claim 1 wherein the silicon oxide layer has a WERR of less than or about 2.5.

8. The method of claim 1 wherein the silicon-containing layer comprises a silicon-and-nitrogen-containing layer and oxygen from the ozone replaces nitrogen from the silicon-and-nitrogen-containing layer during the dual-stage curing operation.

9. The method of claim 1 wherein the silicon-containing layer further comprises hydrogen.

10. The method of claim 1 wherein the silicon-containing layer is carbon-free.

11. The method of claim 1 further comprising forming the silicon-containing layer before the dual-stage curing operation, wherein the silicon-containing layer is flowable during formation.

12. The method of claim 1 wherein the silicon oxide layer consists essentially of silicon and oxygen.

13. The method of claim 1 wherein the plasma power during the second curing stage is between about 300 Watts and about 600 Watts.

14. The method of claim 1 wherein the plasma power during the second curing stage is less than or about 2000 Watts.

15. The method of claim 1 wherein the substrate is patterned and has a trench having a width of about 50 nm or less.

16. The method of claim 15 wherein the silicon oxide layer in the trench is substantially void-free after the dual-stage curing operation.

17. The method of claim 1 wherein the silicon-containing layer comprises a carbon-free silicon-nitrogen-and-hydrogen-containing layer formed by:
flowing an unexcited precursor into a remote plasma region to produce a radical precursor;
combining a carbon-free silicon-containing precursor with the radical precursor in the substrate processing region, wherein the substrate processing region is plasma-free; and
depositing the carbon-free silicon-nitrogen-and-hydrogen-containing layer on the substrate.

18. The method of claim 17 wherein the unexcited precursor comprises at least one of N₂H₂, NH₃, N₂ and H₂.

19. The method of claim 17 wherein the carbon-free silicon-containing precursor comprises a carbon-free silicon-and-nitrogen-containing precursor.

20. The method of claim 17 wherein the carbon-free silicon-containing precursor comprises N(SiH₃)₃.
